(19) United States
(12) Patent Application Publication
(10) Pub. No.: US 2006/0126267 A1
(43) Pub. Date: Jun. 15, 2006

(54) Thin film capacitor for reducing power supply noise

(75) Inventors: Yukio Sakashita, Chuo-ku (JP); Hiroshi Funakubo, Kawasaki-shi (JP)

Correspondence Address: OLIFF & BERRIDGE, PLC, P.O. BOX 19928, ALEXANDRIA, VA, 22320, US

(73) Assignee: TDK CORPORATION, Chuo-ku, Tokyo (JP)

(21) Appl. No.: 10/534,728

(22) PCT Filed: Nov. 11, 2003
(86) PCT No.: PCT/JP03/14305

§ 371 Date: Dec. 2, 2005

(30) Foreign Application Priority Data
Nov. 12, 2002 (JP) 2002-328570

(51) Int. Cl. H01G 4/228

(52) U.S. Cl. 361/306.3

(57) ABSTRACT

A decoupling capacitor connected to a power source for reducing power source noise. The capacitor has a dielectric thin film 8, the dielectric thin film 8 is comprised of a bismuth layer structured compound with ac axis oriented substantially perpendicularly to the plane of a thin film forming substrate, the bismuth layer structured compound is expressed by the formula (Bi₂O₂)²⁺(Aₘ₋₁BₘO₃ₘ₊₁)²⁻ or Bi₂Aₘ₋₁BₘO₃ₘ₊₃, the symbol m in said formula is a positive number, the symbol A is at least one element selected from Na, K, Pb, Ba, Sr, Ca, and Bi, and the symbol B is at least one element selected from Fe, Co, Cr, Ga, Ti, Nb, Ta, Sb, V, Mo, and W

### TECHNICAL FIELD

The present invention relates to a thin film capacitor for reducing power source noise used for applications of reducing power source noise such as a decoupling capacitor and bypass capacitor.

### BACKGROUND ART

If a semiconductor circuit (LSI) is subjected to a sudden load, the parasitic resistance and parasitic inductance present between the power source and the interconnects of the LSI will cause a voltage drop to occur. This voltage drop becomes larger the larger the parasitic resistance and parasitic inductance and becomes larger the shorter the fluctuation time of the load current.

In recent years, along with the increasingly higher operating frequencies of LSIs, the clock startup times have become very short and the voltage drops have become increasingly larger. This easily causes the LSIs to malfunction.

To prevent such malfunctions, malfunctions due to power source noise (including switching noise) are prevented by connecting decoupling capacitors to the power source in parallel and reducing the noise impedance of the power line.

The required power source impedance is proportional to the drive voltage and is inversely proportional to the number of integrations per LSI, the switching current, and the drive frequency. Therefore, along with greater integration, lower voltage, and higher frequency of LSIs in recent years, it is required that the power source impedance become rapidly smaller. To reduce the power source impedance, lowering the inductance and increasing the capacity of the decoupling capacitor are necessary. Therefore, to take maximum advantage of the functions of a decoupling capacitor, the decoupling capacitor has to be arranged as close as possible to the LSI and reduced in inductance.

As a decoupling capacitor, an electrolytic capacitor or multilayer ceramic capacitor is used, but these capacitors are relatively large in size and physically difficult to arrange close to an LSI. Therefore, for example, as shown in Patent Document 1: Japanese Patent Publication (A) No. 2001-15382, a thin film capacitor has been proposed.

However, in the thin film capacitor described in Patent Document 1 etc., as said dielectric thin film, PZT, PLZT, (Ba,Sr)TiO₃ (BST), Ta₂O₅, andother dielectric thin films are used, so there are problems in the temperature characteristics at a high temperature. For example, with BST, the electrostatic capacity at 80° C. exhibits a temperature change of-1000 to-4000 ppm/° C. and so is poor in temperature characteristic compared with the electrostatic capacity at 20° C., so there is a problem when arranging the capacitor near an LSI which sometimes reaches a temperature of as high as 80° C. or more.

Further, these conventional dielectric thin films tend to drop in dielectric constant when the thicknesses of the dielectric thin films are reduced (for example to 100 nm or less). Further, these conventional dielectric thin films have problems in surface smoothness as well. If the thicknesses of the dielectric thin films are reduced, there are also the problems of poor insulation etc. That is, with the conventional thin film capacitors, there were limits to the reduction of size and increase of capacity.

Still further, these conventional dielectric thin films had the problem of a great drop in electrostatic capacity when the thicknesses of the dielectric thin films were reduced and for example a 100 kV/cm field was applied.

Note that as shown in Nonpatent Document 1: “Particle Orientation for Bismuth Layer-Structured Ferroelectric Ceramic and Its Application To Piezoelectric and Pyroelectric Materials”, Tadashi Takenaka, doctoral dissertation of engineering at Kyoto University (1984), Chapter 3, pages 23 to 77, a composition of the formula (Bi₂O₂)²⁺(Aₘ₋₁BₘO₃ₘ₊₁)²⁻ or Bi₂Aₘ₋₁BₘO₃ₘ₊₃, where the symbol m in said formula is a positive number of 1 to 8, the symbol A is at least one element selected from Na, K, Pb, Ba, Sr, Ca, and Bi, and the symbol B is at least one element selected from Fe, Co, Cr, Ga, Ti, Nb, Ta, Sb, V, Mo, and W forms a bulk bismuth layer structured compound dielectric by sintering is itself known.

However, this document did not disclose anything regarding the under what conditions (for example, the relationship between the plane of the substrate and the c axis orientation of the compound) a relatively high dielectric constant and low loss can be given even when making the composition of the above formula a thin film (for example, not more than 1 μm) and a thin film superior in leakage characteristic, improved in breakdown voltage, superior in temperature characteristic of the dielectric constant, and superior in surface smoothness can be obtained.

### DISCLOSURE OF INVENTION

The present invention was made in consideration of this situation and has as its object to provide a capacitor small enough in size to be able to be arranged near an LSI for example, with little change in characteristics even at a high temperature, with little bias dependency, large in capacity and low in dielectric loss, and suitable for use as a thin film capacitor for reducing power source noise such as a decoupling capacitor or bypass capacitor.

The inventors engaged in intensive studies on the material and crystal structure of the dielectric thin films used for capacitors and as a result discovered that by using a specific composition of a bismuth layer structured compound and orienting the c axis ([001] direction) of the bismuth layer structured compound vertically with respect to the plane of the thin film forming substrate, it is possible to provide a capacitor suitable as a thin film capacitor for reducing power source noise. That is, the inventors discovered that by forming a c axis oriented film of a bismuth layer structured compound on the surface of the thin film forming substrate (thin film normal parallel to c axis), it is possible to realize a dielectric thin film which, even if thin, has a relatively high dielectric constant and low loss (low tanδ), is superior in the temperature characteristic of the dielectric constant, and is superior in surface smoothness.

The capacitor according to the present invention is

a thin film capacitor for reducing power source noise connected to a power source for reducing power source noise, characterized in that

said capacitor has a dielectric thin film,

said dielectric thin film is comprised of a bismuth layer structured compound wherein the c axis is oriented substantially vertically with respect to the plane of the thin film forming substrate, and

said bismuth layer structured compound is expressed by the formula (Bi₂O₂)²⁺(Aₘ₋₁BₘO₃ₘ₊₁)²⁻ or Bi₂Aₘ₋₁BₘO₃ₘ₊₃, where the symbol m in said formula is a positive number, the symbol A is at least one element selected from Na, K, Pb, Ba, Sr, Ca, and Bi, and the symbol B is at least one element selected from Fe, Co, Cr, Ga, Ti, Nb, Ta, Sb, V, Mo, and W.

Preferably, said capacitor is a decoupling capacitor connected in parallel between the power source and an integrated circuit. Alternatively, said capacitor may be a bypass capacitor.

Preferably, said capacitor is arranged in contact with an integrated circuit chip (LSI). The capacitor of the present invention is small in size and superior in temperature characteristic, so may also be arranged in contact with the integrated circuit chip.

Alternatively, said capacitor may be arranged between an LSI and a circuit board. Even when the distance between the LSI and circuit board is small, since the capacitor of the present invention is small, it may be arranged between the LSI and circuit board.

Alternatively, the capacitor of the present invention may be mounted buried in a recess of a circuit board, may be mounted on the surface of a circuit board, may be formed integrally at the inside of a circuit board, or may be arranged inside or at the surface of a connection socket. In any case, the capacitor of the present invention is small in size, so can be arranged at any location.

Preferably, said capacitor is a thin film capacitor having a lower electrode formed on said thin film forming substrate, said dielectric thin film formed on said lower electrode, and an upper electrode formed on said dielectric thin film. These lower electrode, dielectric thin film, and upper electrode are formed on the surface of the thin film forming substrate by a thin film forming method. Alternatively, said capacitor may have a multilayer structure comprised of a plurality of said dielectric thin films stacked via electrodes.

Note that the capacitor of the present invention may be formed on the surface of the thin film forming substrate by a thin film formation method, then cut off by a dicer etc., formed into a chip, and soldered to or buried in an integrated circuit, circuit board (intermediate circuit board, intermediate connecting member, etc.), socket, etc. Alternatively, the capacitor of the present invention may be formed by a thin film formation method directly on an LSI, circuit board, socket, etc.

Said thin film forming substrate is not particularly limited, but a single crystal material is preferred. However, an amorphous material or a polyimide or other synthetic resin etc. may also be used. The lower electrode formed on the thin film forming substrate is preferably formed in the [100] direction. By forming the lower electrode in the [100] direction, it is possible to make the c axis of the bismuth layer structured compound forming the dielectric thin film formed on it be oriented vertically with respect to the plane of the thin film forming substrate.

In the present invention, it is particularly preferable that the c axis of the bismuth layer structured compound be oriented 100% vertically with respect to the plane of the thin film forming substrate, that is, the c axis orientation of the bismuth layer structured compound be 100%, but the c axis orientation does not necessarily have to be 100%. Preferably, the c axis orientation of said bismuth layer structured compound is at least 80%.

Preferably, the m in the formula forming said bismuth layer structured compound is any of 1 to 7, more preferably any of 1 to 5. This is because production is easy.

Preferably, said bismuth layer structured compound includes a rare earth element (at least one element selected from Sc, Y, La, Ce, Pr, Nd, Pm, Sm, Eu, Gd, Tb, Dy, Ho, Er, Tm, Yb, and Lu).

The method of production of the dielectric thin film of the capacitor according to the present invention is not particularly limited, but for example it may be produced by using a cubic system, tetragonal system, orthorhombic system, monoclinic system, or other [100] direction oriented thin film forming substrate to form a dielectric thin film having as its main ingredient a bismuth layer structured compound of the formula (Bi₂O₂)²⁺(Aₘ₋₁BₘO₃ₘ₊₁)²⁻ or Bi₂Aₘ₋₁BₘO₃ₘ₊₃, where the symbol m in said formula is a positive number, the symbol A is at least one element selected from Na, K, Pb, Ba, Sr, Ca, and Bi, and the symbol B is at least one element selected from Fe, Co, Cr, Ga, Ti, Nb, Ta, Sb, V, Mo, and W.

The dielectric thin film formed by the above composition of bismuth layer structured compound oriented in the c axis, even if reduced in thickness, has a relatively high dielectric constant (for example a specific dielectric constant of over 100) and a low loss (tans of 0.02 or less), is superior in leakage characteristic (for example, has a leakage current measured at a field strength of 50 kV/cm of 1×10⁻⁷ A/cm² or less and a short-circuit rate of 10% or less), an improved breakdown voltage (for example, 1000 kV/cm or more), a superior temperature characteristic of the dielectric constant (for example, an average rate of change of the dielectric constant with respect to temperature of within ±200 ppm/° C. at a reference temperature of 25° C.), and superior surface smoothness (for example, a surface roughness RA of 2 nm or less).

Further, the dielectric thin film of the capacitor according to the present invention, even if thin, can maintain a relatively high dielectric constant, has a good surface smoothness, enables an increase in capacity even with a single layer, and can be stacked in multiple layers to obtain a further larger capacity.

Further, the capacitor of the present invention is superior in frequency characteristic (for example, the ratio at a specific temperature of the value of the dielectric constant at a high frequency region of 1 MHz and the value of the dielectric constant at a low frequency region of 1 kHz is, in absolute value, 0.9 to 1.1) and superior in voltage characteristic as well (for example, the ratio at a specific frequency of the value of the dielectric constant at a measurement voltage of 0.1V and the value of the dielectric constant at a measurement voltage of 5V is, in absolute value, 0.9 to 1.1).

Still further, the capacitor of the present invention is superior in the temperature characteristic of the electrostatic capacity (the average rate of change of the electrostatic capacity with respect to temperature is within +200 ppm/° C. at a reference temperature of 25° C.)

Note that the “thin film” referred to in the present invention means a film of a material of a thickness of 0.2 nm to several microns formed by various thin film formation methods and excludes a bulk of a thickness of several hundred micro-meters or more formed by sintering. The “thin film” includes continuous films continuously covering a predetermined region and also intermittent films intermittently covering it at any intervals. The thin film may be formed at part or formed at all of the thin film forming substrate surface.

### BRIEF DESCRIPTION OF THE DRAWINGS

Below, the present invention will be explained in detail based on the embodiments shown in the drawings.

FIG. 1 is a schematic cross-sectional view of a capacitor according to an embodiment of the present invention.

FIG. 2 is a circuit diagram showing an application of the capacitor shown in FIG. 1.

FIG. 3 is a schematic view of an example of the position of arrangement of the capacitor shown in FIG. 1.

FIG. 4 is a graph of the frequency characteristic of a capacitor according to an embodiment of the present invention.

FIG. 5 is a graph of the voltage characteristic of a capacitor according to an embodiment of the present invention.

### BEST MODE FOR WORKING THE INVENTION

### First Embodiment

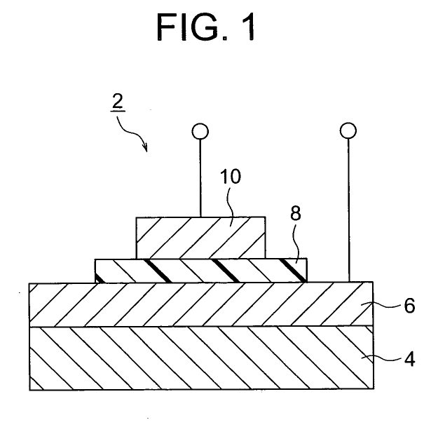

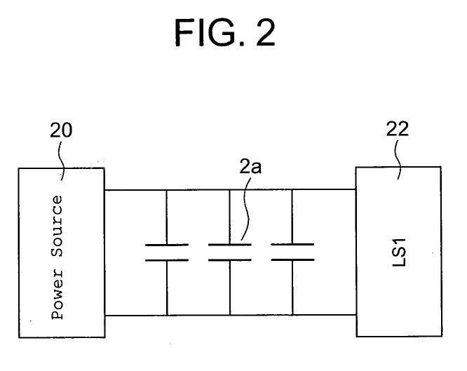

The thin film capacitor for reducing power source noise 2 according to the embodiment shown in FIG. 1 is a thin film capacitor formed by a single layer of a dielectric thin film. This capacitor 2, for example as shown in FIG. 2, may be used as a decoupling capacitor 2a or may be used as a bypass capacitor.

As shown in FIG. 2, the decoupling capacitor 2a is connected in parallel between the power source 20 and semiconductor integrated circuit (LSI) 22 to reduce the power source noise. Further, even when the capacitor of the present invention is used as a bypass capacitor, the power source noise can be reduced.

As shown in FIG. 1, the capacitor 2 has a thin film forming substrate 4. This thin film forming substrate 4 is formed on it with a lower electrode thin film 6. The lower electrode thin film 6 is formed on it with a dielectric thin film 8. The dielectric thin film 8 is formed on it with an upper electrode thin film 10.

As the thin film forming substrate 4, a single crystal with a good lattice match (for example, SrTiO₃ single crystal, MgO single crystal, LaAlO₃ single crystal, etc.), amorphous material (for example, glass, fused quartz, SiO₂/Si, etc.), synthetic resin (for example, a polyimide resin), or other material (for example, ZrO₂/Si, CeO₂/Si, etc.) etc. is used. In particular, it is preferably formed by a cubic system, tetragonal system, orthorhombic system, monoclinic system, or other [100]direction oriented thin film forming substrate. The thickness of the thin film forming substrate 4 is not particularly limited, but for example is about 10 to 1000 μm or so.

As the lower electrode thin film 6 in the case of making the thin film forming substrate 4 using a single crystal with a good lattice match, for example, CaRuO₃ or SrRuO₃ or other conductive oxide or Pt or Ru or other precious metal is preferably used, more preferably a [100]direction oriented conductive oxide or precious metal is used. If using as the thin film forming substrate 4 one oriented in the [100] direction, it is possible to form on its surface a [100] direction oriented conductive oxide or precious metal. By making the lower electrode thin film 6 by a [100] direction oriented conductive oxide or precious metal, the orientation in the [001] direction of the dielectric thin film 8 formed on the lower electrode thin film 6, that is, the c axis orientation, is improved. Such a lower electrode thin film 6 is fabricated by an ordinary thin film formation method, but for example it is preferable to form it by sputtering or pulse laser deposition (PLD) or other physical deposition during which making the temperature of the thin film forming substrate 4 on which the lower electrode thin film 6 is formed preferably 300° C. or more, more preferably 500° C. or more.

As the lower electrode thin film 6 when making the thin film forming substrate 4 using an amorphous material, for example, ITO or another conductive glass may be used. When making the thin film forming substrate 4 using a single crystal with a good lattice match, formation of a lower electrode thin film 6 oriented at its surface in the [100] direction is easy. Due to this, the c axis orientation of the dielectric thin film 8 formed on said lower electrode thin film 6 is easily raised. However, even if the thin film forming substrate 4 is made using glass or another amorphous material, it is possible to form a dielectric thin film 8 improved in c axis orientation. In this case, it is necessary to optimize the film forming conditions of the dielectric thin film 8.

As the other lower electrode thin film 6, for example, gold (Au), palladium (Pd), silver (Ag), or another precious metal or their alloys and also nickel (Ni), copper (Cu), or other base metals or their alloys may be used.

The thickness of the lower electrode thin film 6 is not particularly limited, but is preferably 10 to 1000 nm, more preferably 50 to 100 nm or so.

The upper electrode thin film 10 may be formed by a material similar to that of the lower electrode thin film 6. Further, the thickness may also be made similar.

The dielectric thin film 8 is an example of a composition for a thin film capacitance element of the present invention and contains a bismuth layer structured compound of the formula (Bi₂O₂)²⁺(Aₘ₋₁BₘO₃ₘ₊₁)²⁻ or Bi₂Aₘ₋₁BₘO₃ₘ₊₃. In general, the bismuth layer structured compound exhibits a layer structure of a layer structured perovskite layer of a series of perovskite lattices comprised of (m−1) number of ABO₃ sandwiched above and below by a Bi and O layer. In the present embodiment, the orientation of the bismuth layer structured compound in the [001] direction, that is, the c axis orientation, is improved. That is, the dielectric thin film 8 is formed so that the c axis of the bismuth layer structured compound is oriented perpendicularly to the thin film forming substrate 4.

In the present invention, the c axis orientation of the bismuth layer structured compound is particularly preferably 100%, but the c axis orientation need not be 100%. It is sufficient that preferably 80% or more of the bismuth layer structured compound, more preferably 90% or more, still more preferably 95% or more be oriented in the c axis. for example, when using a glass or other amorphous material thin film forming substrate 4 to orient the bismuth layer structured compound in the c axis, the c axis orientation of said bismuth layer structured compound is preferably 80% or more. Further, when using a later explained thin film formation method to orient the bismuth layer structured compound in the c axis, the c axis orientation of said bismuth layer structured compound is preferably 90% or more, more preferably 95% or more.

The c axis orientation (F) of the bismuth layer structured compound referred to here is found by F (%)=(P−P0)/(1−P0)×100 (equation 1) where the X-ray diffraction intensity of the c axis of the polycrystal completely randomly oriented is P0 and the actual X-ray diffraction intensity of the c axis is P. The “P” referred to in equation 1 is the ratio ({ΣI (001)/ΣI (hkl)}) of the total ΣI (001) of the reflection intensities I (001) from the (001) plane and the total ΣI (hkl) of the reflection intensities (hkl) from the crystal planes (hkl). The same is true for P0. However, in equation 1, the X-ray diffraction intensity P in the case of 100% orientation in the c axis direction is made 1. Further, from equation 1, when completely randomly oriented (P=P0), F=0%, while when completely oriented in the c axis direction (P=1), F=100%.

Note that the c axis of the bismuth layer structured compound means the direction where the pair of (Bi₂O₂)²⁺ layers are connected, that is, the [001] direction. By orienting the bismuth layer structured compound in the c axis in this way, the dielectric properties of the dielectric thin film 8 are exhibited to the maximum extent. That is, even if making the thickness of the dielectric thin film 8 for example 100 nm or less, it is possible to give a relatively high dielectric constant and low loss (low tanδ), the leakage characteristic is superior, the breakdown voltage is improved, the temperature characteristic of the dielectric constant is superior, and the surface smoothness is superior. If the tanδis reduced, the loss Q (1/tanδ) value rises.

In the formula, the symbol m is not particularly limited in meaning so long as it is a positive number.

Note that when the symbol m is an even number, the material has a mirror surface parallel to the c plane, so the c axial components of spontaneous polarization cancel each other out across the mirror surface, so there is no axis of polarization in the c axis direction. Therefore, the dielectric property is maintained, the temperature characteristic of the dielectric constant is improved, and a low loss (low tanδ) is realized.

In the formula, the symbol A indicates at least one element selected from Na, K, Pb, Ba, Sr, Ca, and Bi. Note that when the symbol A indicates two or more elements, they may be in any ratio.

In the formula, the symbol B indicates at least one element selected from Fe, Co, Cr, Ga, Ti, Nb, Ta, Sb, V, Mo, and W. Note that when the symbol B indicates two or more elements, they may be in any ratio. In the present invention, particularly preferably the bismuth layer structured compound is expressed by the chemical formula CaₓSr₍₁₋ₓ₎Bi₄Ti₄O₁₅, where x in the chemical formula is 0≦x≦1. In the case of this composition, the temperature characteristic is improved.

The dielectric thin film 8 preferably further includes, besides said bismuth layer structured compound, at least one element Re selected from Sc, Y, La, Ce, Pr, Nd, Pm, Sm, Eu, Gd, Tb, Dy, Ho, Er, Tm, Yb, and Lu (rare earth element including Y). The amount of substitution by the rare earth element differs depending on the value of m, but for example when m=3, in the formula Bi₂A_{2-xRe}ₓB₃O₁₂, preferably 0.4≦X≦1.8, more preferably 1.0≦X≦1.4. By substitution by a rare earth element in this range, the Curie temperature of the dielectric thin film 8 (phase transition temperature from ferroelectric to dielectric) can be kept to preferably −100° C. to 100° C., more preferably −50° C. to 50° C. If the Curie temperature is from −100° C. to +100° C., the dielectric constant of the dielectric thin film 8 rises. The Curie temperature can also be measured by DSC (differential scan calorimetry) etc. Note that if the Curie temperature becomes less than room temperature (25° C.), the tanδ further decreases and as a result the loss Q value further rises.

Further, for example, when m is an even number, that is, m=4, in the formula Bi₂A₃₋ₓReₓB₄O₁₅, preferably 0.01≦x≦2.0, more preferably 0.1≦x≦1.0.

Note that the dielectric thin film 8 is superior in leakage characteristic as explained later even if not having any rare earth element Re, but by Re substitution, a more superior leakage characteristic can be obtained.

For example, in a dielectric thin film 8 not having a rare earth element Re, the leakage current when measured at a field strength of 50 kV/cm can be made preferably 1×10⁻⁷ A/cm² or less, more preferably 5×10⁻⁸ A/cm² or less, and the short-circuit rate can be made preferably 10% or less, more preferably 5% or less.

As opposed to this, in a dielectric thin film 8 having a rare earth element Re, the leakage current when measured under the same conditions can be made preferably 5×10⁻⁸ A/cm² or less, more preferably 1×10⁻⁸ A/cm² or less, and the short-circuit rate can be made preferably 5% or less, more preferably 3% or less.

The dielectric thin film 8 may be formed using vacuum deposition, high frequency sputtering, pulse laser deposition (PLD), MOCVD (Metal Organic Chemical Vapor Deposition), the liquid phase method (CSD method), and other various thin film formation methods. When necessary to form a dielectric thin film 8 at particularly a low temperature, the plasma CVD, optical CVD, laser CVD, optical CSD, or laser CSD method is preferable.

In the present embodiment, a thin film forming substrate oriented in a specific direction ([100] direction etc.) is used to form the dielectric thin film 8. From the viewpoint of reducing the production cost, using a thin film forming substrate 4 formed by an amorphous material is more preferable. If using such a formed dielectric thin film 8, a specific composition of a bismuth layer structured compound is oriented in the c axis. In such a dielectric thin film 8 and thin film capacitor 2 using this, even if the thickness of the dielectric thin film is reduced to for example 200 nm or less, a relatively high dielectric constant and low loss can be given, the leakage characteristic is superior, the temperature characteristic of the dielectric constant is superior, and the surface smoothness is also superior.

Since the dielectric thin film 8 can be made thin, increase of the capacity and reduction of the size of the capacitor 2 can be simultaneously realized. In the present embodiment, the overall thickness including the thin film forming substrate and electrode in the capacitor 2 can be reduced to about 10 to 100 μm or so.

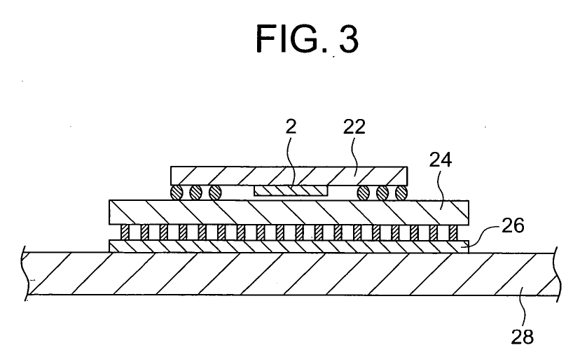

Further, the dielectric thin film 8 is particularly superior in temperature characteristic at a high temperature and has little change in the dielectric constant even at a high temperature (for example, 120° C.) Therefore, the capacitor 2 having this dielectric thin film 8 can be arranged for example as a decoupling capacitor, as shown in FIG. 3, between the LSI 22 and intermediate circuit board 24 in close contact with the LSI. The LSI 22 and intermediate circuit board 24 are connected by solder bumps. The distance between them is becoming smaller as a general trend, but this capacitor 2 is extremely thin, so can be mounted between them.

Further, the LSI 22 becomes high in temperature at some times, but the dielectric thin film of the capacitor 2 is superior in temperature characteristic, so exhibits little change in characteristics even at a high temperature and is superior in noise reducing effect.

Note that the present invention is not limited to the above embodiments and can be modified in various ways in the scope of the present invention. For example, the position of arrangement of the capacitor 2 is not limited to between the LSI 22 and intermediate circuit board 24 shown in FIG. 3. The capacitor may also be mounted buried in a recess of the circuit board 24 or mother board (circuit board) 28, mounted on the surface of the circuit board 24 or 28, formed integrally inside the circuit board 24 or 28, or arranged inside a connection socket 26. In each case, the capacitor of the present invention is small in size, so can be arranged at any location. The capacitor of the present invention can be arranged near the LSI in this way, so the inductance can be lowered. Note that the capacitor of the present invention may also be formed directly at the LSI 22, intermediate circuit board 24, mother board 28, etc.

Further, a plurality of the dielectric thin films 8 may also be stacked on the surface of the thin film forming substrate via electrode films. The dielectric thin film of the capacitor of the present invention is superior in surface smoothness, so even if thin is superior in insulation ability and breakdown voltage, so a greater number can be stacked compared with the past.

### EXAMPLES

Below, the present invention will be explained based on detailed examples, but the present invention is not limited to these examples.

### Example 1

A SrTiO₃ single crystal substrate ((100) SrRuO₃//(100) SrTiO₃) obtained by epitaxially growing SrRuO₃ for forming the lower electrode thin film in the

direction was heated to 700° C. Next, the SrRuO₃ lower electrode thin film was formed on its surface, using Ca(C₁₁H₁₉O₂)₂(C₈H₂₃N₅)₂, Sr (C₁₁H₁₉O₂)₂(C₈H₂₃N₅)₂, Bi (CH₃)₃, and Ti (O-i-C₃H₇)₄ as materials and MOCVD, with a plurality of approximately 100 nm thick CaₓSr₍₁₋ₓ₎Bi₄Ti₄O₁₅ thin films (dielectric thin films) changed in x to x=0, 1. The value of x was controlled by adjusting the flow rates of the carrier gases of the Ca material and Sr material. Note that in the above chemical formula, when x=0, the result is a SrBi₄Ti₄O₁₅ thin film (SBTi thin film/formula Bi₂Aₘ₋₁BₘO₃ₘ₊₃ where symbol m=4, symbol A₃=Sr+Bi₂, and symbol B₄=Ti₄). Further, when x=1, the result becomes a CaBi₄Ti₄O₁₅ thin film (CBTi thin film/formula Bi₂Aₘ₋₁BₘO₃ₘ₊₃ where symbol m=4, symbol A₃=Ca+Bi₂, and symbol B₄=Ti₄)

The crystalline structures of these dielectric thin films were measured by X-ray diffraction (XRD), whereupon it could be confirmed that they were oriented in the [001] direction, that is, the c axis was oriented perpendicularly to the plane of the SrTiO₃ single crystal substrate. Further, the surface roughnesses (Ra) of these dielectric thin films were measured based on the JIS-B0601 by an AFM (atomic force microscope, made by Seiko Instruments, SPI3800).

Next, these dielectric thin films were formed on their surfaces with 0.1 mmφ Pt upper electrode thin films by the sputtering method to prepare samples of the thin film capacitor.

The electrical characteristics of the obtained capacitor sample (dielectric constant, tanδ, loss Q value, leakage current, breakdown voltage) and the temperature characteristic of the dielectric constant were evaluated. The dielectric constant (no unit) was calculated from the electrostatic capacity of the capacitor sample measured using a digital LCR meter (made by YHP, 4274A) under conditions of room temperature (25° C.) and a measurement frequency of 100 kHz (AC 20 mV), the electrode dimensions of the capacitor sample, and the electrode distance. tanδ was measured under the same conditions as the conditions for measurement of the electrostatic capacity. Along with this, the loss Q value was calculated.

The leakage current characteristic (unit: A/cm²) was measured at a field strength of 50 kV/cm.

For the temperature characteristic of the dielectric constant, a capacitor sample was measured under the above conditions for dielectric constant, the average rate of change (Δε) of the dielectric constant with respect to temperature in a temperature range of −55 to +150° C. when the reference temperature was made 25° C., and the temperature coefficient (ppm/° C.) was calculated. The breakdown voltage (unit: kV/cm) was measured by raising the voltage in the measurement of the leakage characteristic. The results are shown in Table 1.

TABLE 1

| | | Plane | Direction | | | | | | | | |
|---|---|---|---|---|---|---|---|---|---|---|---|
| | | direction | of | Film | Surface | Withstand | Leakage | | Temp, | | Loss |
| | | of | orientation | thickness | roughness | voltage | current | Dielectric | coefficient | | Q |
| | x | substrate | of film | (nm) | Ra (nm) | (kV/cm) | (A/cm²) | constant | (ppm/° C.) | tanδ | value |
| Ex. 1 | 0 | [100] | [001] | 100 | <2 | >1000 | <1 × 10⁻⁷ | 200 | −150 | <0.02 | >50 |
| Ex. 1 | 1 | [100] | [001] | 100 | <2 | >1000 | <1 × 10⁻⁷ | 230 | 90 | <0.02 | >50 |

Evaluation

As shown in Table 1, it was confirmed that the c axis oriented film of the bismuth layer structured compound obtained in Example 1 had a high breakdown voltage of 1000 kV/cm or more, a low leakage current of 1×10⁻⁷ or less, a dielectric constant of 200 or more, a tanδ of 0.02 or less, and a loss Q value of 50 or more. Due to this, formation of a thinner film can be expected and in turn a higher capacity of a thin film capacitor can be expected.

Further, in Example 1, it could be confirmed that since the temperature coefficient is an extremely small ±150 ppm/° C. or less, the dielectric constant is a relatively large 200 or more and basic characteristics superior for a temperature compensating capacitor material are possessed. Further, in Example 1, it could be confirmed that since the surface smoothness was superior, the thin film material was suitable for producing a multilayer structure. That is, from Example 1, the effectiveness of the c axis oriented film of the bismuth layer structured compound could be confirmed.

### Example 2

In this example, a sample of the thin film capacitor fabricated in Example 1 was used to evaluate the frequency characteristic and voltage characteristic.

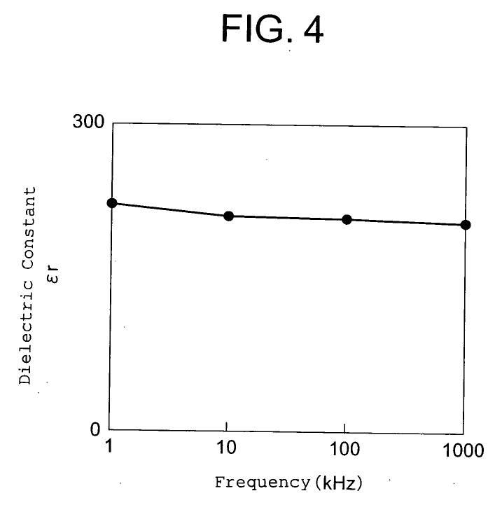

The frequency characteristic was evaluated in the following way. A capacitor sample was measured for electrostatic capacity at room temperature (25° C.) while changing the frequency from 1 kHz to 1 MHz and the dielectric constant was calculated. The results are shown in FIG. 4. The electrostatic capacity was measured using an LCR meter. As shown in FIG. 4, it could be confirmed that even if changing the frequency at a specific temperature to 1 MHz, the value of the dielectric constant did not change. That is, the superior frequency characteristic could be confirmed.

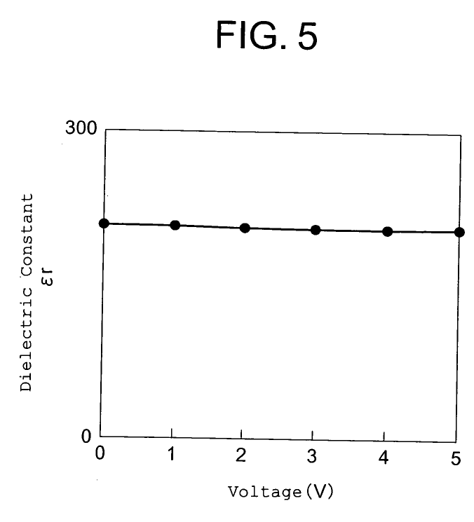

The voltage characteristic was evaluated in the following way. A capacitor sample was measured for electrostatic capacity at a specific voltage while changing the measurement voltage at a specific frequency (100 kHz) (applied voltage) from 0.1V (field strength 5 kV/cm) to 5V (field strength 250 kV/cm) (measurement temperature 25° C.) and the dielectric constant was calculated. The results are shown in FIG. 5. The electrostatic capacity was measured using an LCR meter. As shown in FIG. 5, it was confirmed that even if changing the measurement voltage under a specific frequency to 5V, there was no change in the value of the dielectric constant. That is, it was confirmed that the voltage characteristic was superior.

### Example 3

First, a [100] direction oriented SrTiO₃ single crystal substrate (thickness: 0.3 mm) was prepared, the substrate was masked by a metal mask of a predetermined pattern, and pulse laser deposition was used to form an internal electrode thin film constituted by a SrRuO₃ electrode thin film to a thickness of 100 nm (pattern 1).

Next, pulse laser deposition was used to form on the entire surface of the substrate including the internal electrode thin film a dielectric thin film constituted by a CaₓSr₍₁₋ₓ₎Bi₄Ti₄O₁₅ thin film (dielectric thin film) where x=0 in the same way as in Example 1 to a thickness of 100 nm.

Next, this dielectric thin film was masked by a metal mask of a predetermined pattern and pulse laser deposition was used to form an internal electrode thin film constituted by a SrRuO₃ electrode thin film to a thickness of 100 nm (pattern 2).

Next, pulse laser deposition was used to form on the entire surface of the substrate including the internal electrode thin film another dielectric thin film in the same way as above to a thickness of 100 nm.

This procedure was repeated to stack five layers of dielectric thin film. Further, the dielectric thin film arranged at the outermost part was covered on its surface by a protective layer made of silica to obtain a capacitor body.

Next, the two ends of the capacitor body were formed with a pair of external electrodes made of Ag to obtain a 1 mm length×0.5 mm width×0.4 mm thickness parallelopiped shaped thin film multilayer capacitor sample.

The electrical characteristics of the obtained capacitor sample (dielectric constant, dielectric loss, Q value, leakage current, short-circuit rate) were similarly evaluated as in Example 1, whereupon the dielectric constant was 200, the tanδ was 0.02 or less, the loss Q value was 50 or more, and the leakage current was 1×10⁻⁷ A/cm² or more, i.e., good results were obtained. Further, the temperature characteristic of the dielectric constant of the capacitor sample was evaluated in the same way as Example 1, whereupon the temperature coefficient was found to be −20 ppm/° C.

Above, embodiments and examples of the present invention were explained, but the present invention is not limited to these embodiments and examples in any way and may of course be worked in various forms within the scope not exceeding the gist of the present invention.

As explained above, according to the present invention, it is possible to provide a capacitor small enough in size to be able to be arranged near an LSI for example, with little change in characteristics even at a high temperature, with little bias dependency, large in capacity and low in dielectric loss, and suitable for use as a thin film capacitor for reducing power source noise such as a decoupling capacitor or bypass capacitor.

1. A thin film capacitor for reducing power source noise connected to a power source for reducing power source noise, characterized in that
said capacitor has a dielectric thin film,
said dielectric thin film is comprised of a bismuth layer structured compound wherein the c axis is oriented substantially vertically with respect to the plane of a thin film forming substrate, and
said bismuth layer structured compound is expressed by the formula (Bi₂O₂)²⁺(Aₘ₋₁BₘO₃ₘ₊₁)²⁻ or Bi₂Aₘ₋₁BₘO₃ₘ₊₃, where the symbol min said formula is a positive number, the symbol A is at least one element selected from Na, K, Pb, Ba, Sr, Ca, and Bi, and the symbol B is at least one element selected from Fe, Co, Cr, Ga, Ti, Nb, Ta, Sb, V, Mo, and W.

2. The thin film capacitor for reducing power source noise as set forth in claim 1, wherein said capacitor is a decoupling capacitor connected in parallel between the power source and an integrated circuit.

3. The thin film capacitor for reducing power source noise as set forth in claim 1, wherein said capacitor is a bypass capacitor connected in parallel between the power source and an integrated circuit.

4. The thin film capacitor for reducing power source noise as set forth in claim 2, wherein said capacitor is arranged near an integrated circuit chip.

5. The thin film capacitor for reducing power source noise as set forth in claim 2, wherein said capacitor is arranged in contact with an integrated circuit chip.

6. The thin film capacitor for reducing power source noise as set forth in claim 2, wherein said capacitor is arranged between an integrated circuit chip and a circuit board.

7. The thin film capacitor for reducing power source noise as set forth in claim 2, wherein said capacitor is mounted buried in a recess of a circuit board.

8. The thin film capacitor for reducing power source noise as set forth in claim 2, wherein said capacitor is mounted on the surface of a circuit board.

9. The thin film capacitor for reducing power source noise as set forth in claim 2, wherein said capacitor is formed integrally inside a circuit board.

10. The thin film capacitor for reducing power source noise as set forth in claim 2, wherein said capacitor is arranged at an inside or surface of a connection socket.

11. The thin film capacitor for reducing power source noise as set forth in claim 1, wherein said capacitor has a lower electrode formed on said thin film forming substrate, said dielectric thin film formed on said lower electrode, and an upper electrode formed on said dielectric thin film.

12. The thin film capacitor for reducing power source noise as set forth in claim 1, wherein said capacitor has a multilayer structure comprised of a plurality of said dielectric films stacked via electrodes.

13. The thin film capacitor for reducing power source noise as set forth in claim 1, wherein said capacitor is comprised of a bismuth layer structured compound having a c axis orientation of at least 80%.
